(19) United States
(12) Patent Application Publication
(10) Pub. No.: US 2006/0024953 A1
(43) Pub. Date: Feb. 2, 2006

(54) Dual damascene diffusion barrier/liner process with selective via-to-trench-bottom recess

(76) Inventors: Satyavolu Srinivas Papa Rao, Garland, TX (US); Stephan Grunow, Dallas, TX (US); Noel M. Russell, Plano, TX (US)

Correspondence Address: TEXAS INSTRUMENTS INCORPORATED, P O BOX 655474, M/S 3999, DALLAS, TX, 75265, US

(21) Appl. No.: 10/903,597

(22) Filed: Jul. 29, 2004

(51) Int. Cl. H01L 21/4763

(52) U.S. Cl. 438/629; 438/638; 438/622; 438/626; 438/627; 438/639

(57) ABSTRACT

A method for fabricating a barrier layer. A first barrier layer (124) is deposited over a dielectric (104) including in a trench (108) and via (106). A re-sputtering process is then performed to remove said first barrier layer (124) from a bottom of the via (106) without substantially reducing a thickness of said first barrier layer (124) at a bottom of the trench (108) using an intermediate DC target power. A second barrier layer (126) is then deposited.

### FIELD OF THE INVENTION

The invention is generally related to the field of fabricating integrated circuits and more specifically to fabricating a diffusion barrier/liner in a dual damascene process.

### BACKGROUND OF THE INVENTION

As the density of semiconductor devices increases, the demands on interconnect layers for connecting the semiconductor devices to each other also increases. Copper has increasingly become the metal of choice for fabricating interconnects in integrated circuits. Unfortunately, suitable copper etches for a semiconductor fabrication environment are not readily available. To overcome the copper etch problem, damascene processes have been developed.

In a damascene process, the dielectric is formed first. The dielectric is then patterned and etched. A thin liner/barrier material is then deposited over the structure to prevent diffusion of copper through the dielectric. This is followed by copper deposition over the liner/barrier material. Finally, the copper and liner/barrier material are chemically-mechanically polished to remove the material from over the dielectric, leaving metal interconnect lines.

The most practical technique for forming copper interconnects is electrochemical deposition (ECD). In this process, after the liner/barrier material is deposited, a seed layer of copper is deposited. Then, ECD is used to deposit copper over the seed layer. Unfortunately, physical vapor deposition (PVD) processes typically used to deposit the liner/barrier and seed materials have poor step coverage. This is due to the fact that PVD processes use a line of sight technique. As a result, an overhang of the liner/barrier and/or seed material occurs at the top of a trench or via. The overhang causes a severe problem during the subsequent copper ECD. Specifically, a seam can occur in the copper fill material.

One proposed solution for overcoming the above problem uses a pre-sputter etch after the trench and via or contact etch, but before liner/barrier deposition. Unfortunately, the sputter etch step can deposit copper onto the sidewalls. Copper can then diffuse through the dielectric and cause reliability problems. Also, the use of a pre-sputter etch can lead to faceting/corner rounding of the features, making the adjacent structures more prone to electrical leakage due to a reduction of line-to-line separation distance.

### SUMMARY OF THE INVENTION

The invention is a method of fabricating a diffusion barrier/liner. The method includes the steps of depositing a first barrier layer over a dielectric layer including in a trench and a via, performing a re-sputter etch with an intermediate DC target power optimized to have a higher net etch rate of the first barrier from a bottom of the via than from a bottom of the trench, and depositing a second barrier layer over the first barrier layer.

An advantage of the invention is providing an improved diffusion barrier/liner layer.

This and other advantages will be apparent to those of ordinary skill in the art having reference to the specification in conjunction with the drawings.

### BRIEF DESCRIPTION OF THE DRAWINGS

In the drawings:

FIG. 1 is a cross-sectional diagram of a copper interconnect structure formed according to the invention;

FIGS. 2A-2D are cross-sectional drawings of a copper interconnect structure formed according to an embodiment of the invention at various stages of fabrication.

### DETAILED DESCRIPTION OF THE EMBODIMENTS

The invention will now be discussed with reference to diffusion barrier/liner for a copper dual damascene process. It will be apparent to those of ordinary skill in the art that the invention may be applied to other liner layers and methods for selectively removing such layers different portions of a feature such as a trench/via feature.

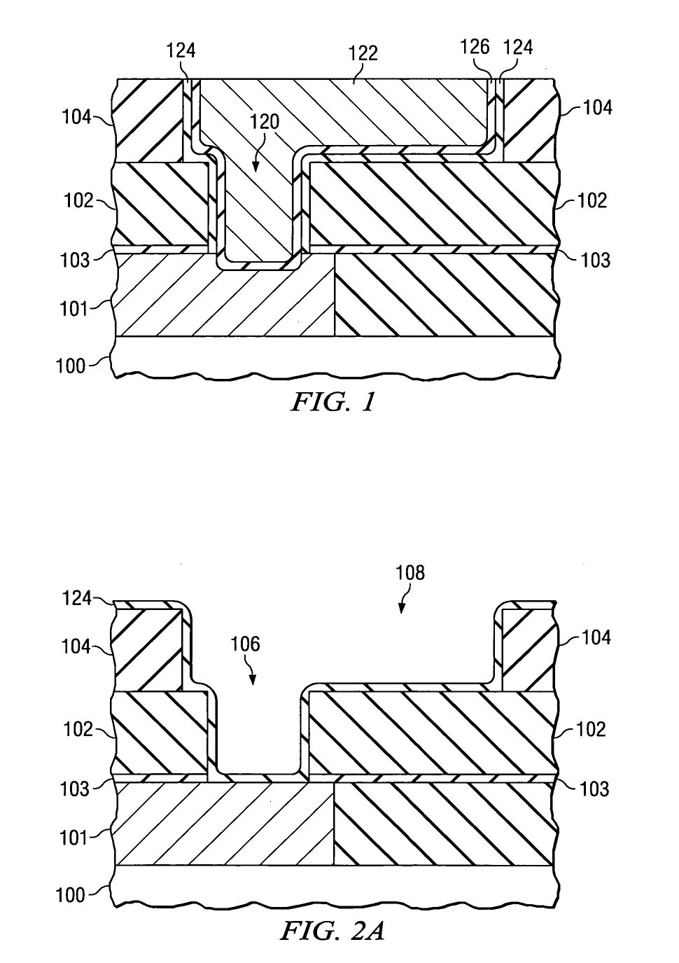

An interconnect structure formed according to an embodiment of the invention is shown in FIG. 1. A via structure 120 extends through an interlevel dielectric (ILD) 102 and connects between a lower copper interconnect 101 and an upper copper interconnect (trench structure 122). Trench structure 122 and via structure 120 comprise a first barrier/liner 124. First barrier liner 124 lines the sidewalls and bottom of trench structure 122 and the sidewalls of the via structure 120. First barrier/liner 124 does not extend along the bottom surface of the via. As will be described further below, a specially tuned re-sputter etch process is used to clear first barrier/liner 124 from a bottom of the via without recessing the bottom of the trench. The thickness of first barrier/liner 124 may be in the range of 0.5-15 nm (as measured on the trench and/or via sidewalls).

First barrier/liner 124 may comprise one of many suitable copper barriers are known in the art. First barrier/liner 124 may, for example, include Ta-, W-, and Ti-based materials, including their nitrides, carbo-nitrides and silicon nitrides, Ru and Ir, and oxides of Ru & Ir. Because first barrier/liner 124 does not extend along the bottom surface of the via, the resistivity of the material used for first barrier/liner 124 is not as critical as the second barrier/liner 126. Accordingly, a wider choice of materials is available. A material having good adhesion properties and good barrier properties against copper diffusion should be selected. For example, amorphous ternary transition metal-silicon nitrides such as TaSiN, TiSiN, MoSiN or WSiN may be used even though they typically have higher resistivity. In a preferred embodiment of the invention Ta is used. In another preferred embodiment an ALD-TaN film is used.

Second barrier/liner 126 is located adjacent the first barrier liner 124 on the sidewalls and bottom of trench structure 122 and on the sidewalls of the via structure 120. Second barrier/liner 126 does extend along the bottom surface of the via. Second barrier/liner 126 is an ultra-thin barrier/wetting layer to protect misaligned vias against a direct Cu-to-dielectric interface and provide adequate surface properties for a subsequent metallization fill step. The thickness of second barrier liner 126 is in the range of 0.5 to 15 nm (as measured on the trench and/or via sidewalls). Second barrier/liner 126 may comprise Ta-, W-, Mo-, and Ti-based materials, including their nitrides, carbo-nitrides and silicon nitrides, Ru and Ir and oxides of Ru and Ir. The second barrier/liner 126 may comprise the same or a different material than first barrier/liner 124. In a preferred embodiment, second barrier/liner 126 also comprises Ta.

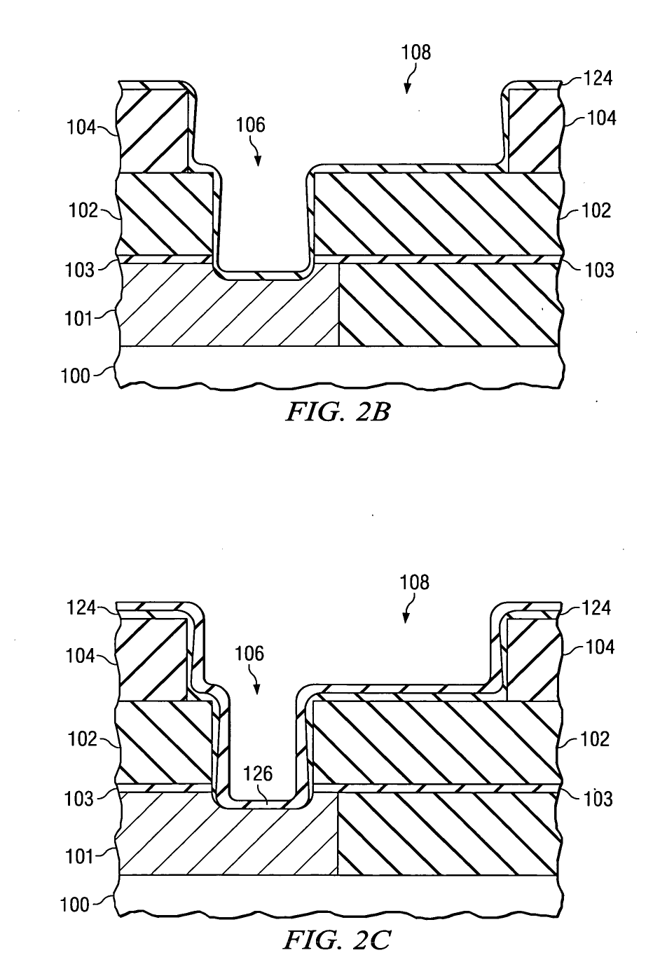

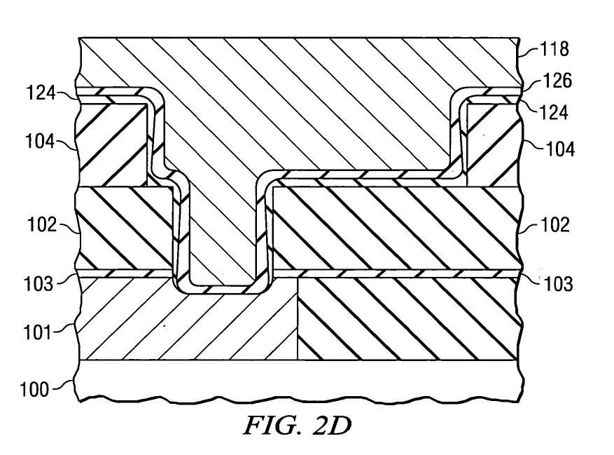

A method for fabricating a copper dual damascene interconnect structure according to an embodiment of the invention will now be discussed with reference to FIGS. 2A-2D. A semiconductor body 100 is processed through formation of trench and vias in a metal interconnect level, as shown in FIG. 2A. Semiconductor body 100 typically comprises a silicon substrate with transistors and other devices formed therein. Semiconductor body 100 may also include one or more metal interconnect layers. One such copper interconnect, 101, is shown.

An ILD (interlevel dielectric) 102 is formed over semiconductor body 100 (including copper interconnect 101). An etchstop layer 103 is typically placed underneath ILD 102. IMD (intrametal dielectric) 104 is formed over ILD 102. An additional etchstop layer (not shown) may optionally be placed between ILD 102 and IMD 104. Suitable dielectrics for ILD 102 and IMD 104, such as silicon dioxides, fluorine-doped silicate glass (FSG), organo-silicate glass (OSG), silsesquioxane (SSQ)-based materials, e.g., MSQ (methylsilsesquioxane) or hydrogensilsesquioxane (HSQ), organic-polymer-based materials, amorphous-carbon-based materials, and any other dielectric material that is suitable to serve as low-dielectric-constant medium are known in the art. ILD 102 and IMD 104 are thick dielectric layers and typically have a thickness in the range of 0.05 um-1 um.

In a copper dual damascene process, both the vias and trenches are etched in the dielectric. Via 106 is etched in ILD 102 (and later through etchstop 101) and trench 108 is etched in IMD 104. Via 106 is used to connect to underlying metal interconnect layer 101. Trench 108 is used to form the metal interconnect lines.

Still referring to FIG. 2A, a first barrier/liner layer 124 is deposited over IMD 104 including in trench 108 and via 106. Suitable deposition techniques, such as PVD (physical vapor deposition), CVD (chemical vapor deposition), and ALD (atomic layer deposition) are known in the art. First barrier/liner layer 124 protects the via sidewalls against Cu re-sputtering in during later steps. The thickness of first barrier/liner layer may be in the range of 0.5-15 nm. Suitable materials, for example, include Ta-, W-, Ti-based materials, including their nitrides, carbo-nitrides and silicon nitrides, Ru, and Ir, and oxides of Ru and Ir. In a preferred embodiment, PVD Ta is used. In another preferred embodiment, ALD-TaN is used.

Referring to FIG. 2B, a re-sputtering process is performed to clear at least a portion and preferably all of first barrier/liner layer 124 from the bottom of via 106 but not clear the first barrier/liner layer 124 from the bottom of the trench 108. Material of first barrier/liner layer 124 is re-sputtered or etched away from the bottom of the via and partly re-deposited on the sidewalls of the via 106 and trench 108. As a side benefit, the re-deposited material may improve sidewall coverage. The re-sputtering process is specifically tuned to remove material from the bottom of via 106 (i.e., recess the bottom of via 106) without recessing the bottom of trench 108. Ordinarily, a sputter process will remove line-of sight material (i.e., material on horizontal surfaces) but not significantly remove material from the sidewalls. Thus, ordinarily, both the trench and via bottoms would be recessed. The re-sputtering process of the invention is accomplished by placing the wafer in a process chamber of a PVD tool and using a specially tuned re-sputter etch with an intermediate DC target power to create a flux of barrier metal neutrals and ions that balances the etch at the trench bottom, but is not adequate to balance the etch at the via bottom. In a preferred embodiment, the deposition and etch components are balanced such that there is a “net zero” effect at the trench bottom where the thickness of the first barrier/liner layer 124 does not change during the re-sputtering step. Alternatively, the thickness of first barrier/liner layer 124 may be reduced at the trench bottom. It should be noted that the resputter process can be continued beyond the removal of the Ta over the copper at the bottom of the via to remove some of the copper as well.

A high DC target power will result in deposition that would overwhelm the etch/re-sputter component and is therefore, not desirable. An intermediate DC target power is below that which results in deposition overwhelming the etch/re-sputter component but high enough to create a rough balance between deposition and etch components at the trench bottom. The intermediate DC target power may be in the range of 500-20000 W. Preferably, the intermediate DC target power is in the range of 2000-10000 W.

The AC wafer power and the RF coil power may be used in conjunction with the intermediate DC target power to control the etch at via bottom due to their effect on the ionization of the plasma and due to the effect of the AC wafer power on the acceleration of the ions towards the wafer. The AC wafer power is a high frequency bias power applied to the wafer through the wafer chucking mechanism. The frequency is typically 13.6 MHz but other allowable radio frequencies may be used. The RF coil power is also a high frequency power that is applied to the plasma coil. The RF coil and AC wafer powers may be scaled to the intermediate DC target power. For example, as the DC target power is increased, the AC wafer and RF coil powers are increased in order to counter the ion flux coming from the target. The AC wafer power may be in the range of 200-2000 W and is preferably in the range of 300-1300 W. The RF coil power is in the range of 500-3200 W and is preferably in the range of 800-2400 W.

A DC coil power may be applied. The DC coil power is in the range of 0-500 W, preferably 0-200 W. The pressure in the process chamber may be in the range of 0-40 mTorr. Preferably, it is in the range of 0-10 mTorr. The above process conditions are suitable for a 200 mm SIP EnCoRe platform available from Applied Materials. The above process conditions may be tuned using the above teachings for other tools, such as 300 mm PVD tools.

By using an intermediate DC target power and appropriately scaled AC wafer and RF coil powers, portions of first barrier/liner layer 124 are removed from the bottom of the via and re-deposited, for example, on the sidewalls of the trench 108 and via 106. The re-sputtering process is continued until the bottom of the via is cleared of first barrier/liner layer 124. (It should be noted that some material of first barrier/liner layer will remain in the bottom corners of the via.) While some of first barrier/liner layer 124 may be removed from the bottom of the trench 108, more material is removed from the bottom of the via 106 such that the bottom of the trench 108 remains covered with first barrier/liner layer 124 when the via bottom is cleared. The resputtering process may also be continued beyond the clearing of barrier metal from the via bottom in order to remove some of the copper from the underlying interconnect 101 and recess the bottom of the via. This removal of the copper can result in the deepest point of the via bottom ranging from 0-70 nm from the etch-stop layer 103 (with 0-30 nm being preferred). Such removal of copper may improve the yield and reliability characteristics of the resulting structure further (for example, in the case where the copper immediately beneath the via has been oxidized or otherwise damaged in the process flow prior to the barrier deposition process).

After the re-sputtering process, a second barrier layer 126 is deposited over the first barrier/liner layer 124, as shown in FIG. 2C. The second barrier layer 126 is an ultra-thin layer to protect misaligned vias against a direct Cu-to-dielectric interface and provide adequate surface properties for subsequent metallization fill steps. The thickness of second barrier layer 126 may be in the range of 0.5-15 nm. Second barrier/liner 126 may comprise Ta-, W-, Mo-, and Ti-based materials, including their nitrides and silicon nitrides, Ru and Ir, and the oxides of Ru and Ir. The second barrier/liner 126 may comprise the same or a different material than first barrier/liner 124. In a preferred embodiment, second barrier/liner 126 also comprises Ta.

In one preferred embodiment, the first barrier/liner layer 124 and second barrier layer 126 are each deposited using a Ta PVD process. In this embodiment, the deposition of the first barrier/liner layer 124, the re-sputtering process, and the depositing of the second barrier layer 126 are all performed in the same PVD tool, possibly in the same chamber of the PVD tool. In a second preferred embodiment, where ALD-TaN forms the first barrier/liner layer 124, and PVD Ta forms the second barrier layer 126, the barrier formation is preferably accomplished with the use of two different chambers of the same PVD tool (though it is possible to deposit ALD in one tool, and accomplish the specially tuned etch and barrier layer 126 in a second, PVD, tool)

After forming the second barrier layer 126, a Cu seed layer (not shown) is typically deposited over the structure. Copper ECD is then performed as shown in FIG. 2D to form copper layer 118. Various copper ECD processes are known in the art. In one example, a 3-step low acid process is used. The wafer is placed in a plating solution with an applied current. A direct current is used. Plating occurs in three steps using a different plating current at each step to control the deposition rate and quality.

Processing then continues to chemically-mechanically polish (CMP) the copper layer 118 and barrier/liner 124 to form the copper interconnect, as shown in FIG. 1. Also, other means of removal of excess metal can be used, such as electro-polishing. Additional metal interconnect layers may then be formed followed by packaging.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, the invention may be applied to forming contacts instead of vias. It is therefore intended that the appended claims encompass any such modifications or embodiments.

1. A method of fabricating an integrated circuit, comprising the steps of:
forming a dielectric layer;
forming a trench and a via in said dielectric layer;
depositing a first barrier layer over said dielectric layer including in said trench and said via;
performing a re-sputter etch in a physical vapor deposition tool with an intermediate DC target power, wherein the re-sputter etch results in a higher etch rate at a bottom of said via than at a bottom of said trench;
depositing a second barrier layer over said first barrier layer.

2. The method of claim 1, wherein said re-sputter etch step continues until at least a portion of said first barrier layer is etched through at said bottom of said via.

3. The method of claim 1, wherein said re-sputter etch step removes copper from below the bottom of said via.

4. The method of claim 1, wherein said re-sputter etch step comprises a AC wafer power and a RF coil power selected in conjunction with said intermediate DC target power to remove said first barrier layer at the bottom of the via while substantially maintaining a thickness of said first barrier layer at the bottom of said trench.

5. The method of claim 4, wherein said AC wafer power is in the range of 300-700 W, said RF coil power is in the range of 800-2400 W, and said intermediate DC target power is in the range of 2000-10000 W.

6. The method of claim 3, wherein said AC wafer power is in the range of 200-1000 W, said RF coil power is in the range of 500-3200 W, and said intermediate DC target power is in the range of 500-20000 W.

7. The method of claim 1, wherein said first barrier layer and said second barrier layer each comprise a material selected from the group consisting of Ta, W, Mo, Ti, TaN, WN, MoN, TiN, TaSiN, WSiN, MoSiN, TiSiN, TaCN, WCN, MoCN, and TiCN.

8. The method of claim 1, wherein first barrier layer and said second barrier layer each comprise a material selected from the group consisting of Ru, Ir, RuO₂ and IrO₂.

9. The method of claim 1, wherein said steps of depositing a first barrier layer, performing a re-sputter etch, and depositing a second barrier layer are performed in the same process chamber of a process tool.

10. A method of fabricating an integrated circuit, comprising the steps of:
forming a dielectric layer;
forming a trench and a via in said dielectric layer;
depositing a first barrier layer over said dielectric layer including in said trench and said via;
re-sputtering said first barrier layer to recess a bottom of said via without recessing a bottom of said trench, wherein said re-sputtering process uses an intermediate DC target power to approximately balance a deposition component and an etch component of said re-sputtering process at the bottom of the trench; and
depositing a second barrier layer over said first barrier layer.

11. The method of claim 10, wherein said re-sputtering step completely removes said first barrier layer over at least a portion of said via.

12. The method of claim 10, wherein said re-sputtering step comprises a AC wafer power and a RF coil power selected in conjunction with said intermediate DC target power to remove said first barrier layer at the bottom of the via while substantially maintaining a thickness of said first barrier layer at the bottom of said trench.

13. The method of claim 12, wherein said AC wafer power is in the range of 300-700 W, said RF coil power is in the range of 800-2400 W, and said intermediate DC target power is in the range of 2000-10000 W.

14. The method of claim 12, wherein said AC wafer power is in the range of 200-1000 W, said RF coil power is in the range of 500-3200 W, and said intermediate DC target power is in the range of 500-20000 W.

15. The method of claim 10, wherein said first barrier layer and said second barrier each comprise a material selected from the group consisting of Ta, W, Mo, Ti, TaN, WN, MoN, TiN, TaSiN, WSiN, MoSiN, TiSiN, TaCN, WCN, MOCN, and TiCN

16. The method of claim 10, wherein said first barrier layer and said second barrier layer each comprise a material selected from the group consisting of Ru, Ir, RuO₂ and IrO₂.

17. The method of claim 10, wherein said steps of depositing a first barrier layer, re-sputtering, and depositing a second barrier layer are performed in the same chamber of a process tool.

18. The method of claim 10, wherein said steps of depositing a first barrier layer, re-sputtering, and depositing a second barrier are performed in multiple chambers of a process tool.

19. The method of claim 10, further comprising forming a metal interconnect below a bottom of said via, wherein said re-sputtering step removes a portion of said metal interconnect.
